(19) United States
(12) Patent Application Publication
(10) Pub. No.: US 2023/0116014 A1
(43) Pub. Date: Apr. 13, 2023

(54) MANIPULATOR ARM FOR A ROBOT, AND ROBOT HAVING A MANIPULATOR ARM OF THIS TYPE

(71) Applicant: Schaeffler Technologies AG & Co. KG, Herzogenaurach (DE)

(72) Inventors: Jochen DAMERAU, Tokyo (JP); Tomas SMETANA, Yokahama (JP); Jörg KEGELER, Schleusingen (DE)

(73) Assignee: Schaeffler Technologies AG & Co. KG, Herzogenaurach (DE)

(21) Appl. No.: 17/914,485

(22) PCT Filed: Feb. 24, 2021
(86) PCT No.: PCT/DE2021/100179

§ 371 Date: Sep. 26, 2022

(30) Foreign Application Priority Data
Mar. 24, 2020 (DE) 10 2020 107 990.7

(51) Int. Cl. H02K 3/26; B25J 9/12; B25J 13/08; H02K 7/116; H02K 11/30; H02K 11/21

(52) U.S. Cl. CPC H02K 3/26; B25J 9/12; B25J 13/088; H02K 7/116; H02K 11/30; H02K 11/21; B25J 9/1025

(57) ABSTRACT

A manipulator arm for a robot, including a printed circuit board motor and a transmission, the printed circuit board motor including a multi-layer board having at least one first solenoid coil with flat coils lying vertically on top of each other, the flat coils being connected electrically in series or in parallel, two vertically adjacent coils being orthogonally offset to each other in each case such that, in a cross-section perpendicular to the surface of the multi-layer board, conducting track portions of the one flat coil are arranged in partial overlap vertically with two conducting track portions of the other flat coil. A robot having at least one manipulator arm of this type and the use of a printed circuit board motor in a manipulator arm of a robot are also provided.

### CROSS-REFERENCE TO RELATED APPLICATIONS

This application is the U.S. National Phase of PCT Appln. No. PCT/DE2021/100179, filed Feb. 24, 2021, which claims the benefit of German Pa-tent Appln. No. 10 2020 107 990.7, filed Mar. 24, 2020, the entire disclosures of which are incorporated by reference herein.

### TECHNICAL FIELD

The disclosure relates to a manipulator arm for a robot. Furthermore, the disclosure relates to a robot comprising at least one such manipulator arm. In addition, the use of a circuit board motor in a manipulator arm of a robot is proposed.

### BACKGROUND

DE10 2015 222 400 A1 discloses a printed circuit board for an electric motor, with a coil which is formed from at least one conducting track running spirally within a layer of the printed circuit board. A coil core made of a ferromagnetic or ferrimagnetic material is provided, extending in a direction perpendicular to the sheet. The coil core is provided completely within the printed circuit board and is electrically insulated from the surroundings of the printed circuit board.

### SUMMARY

The object of the present disclosure is to propose a compact manipulator arm for a robot, which enables higher load capacity and higher movement speed. The object is achieved by a compact manipulator arm for a robot having one or more of the features disclosed herein. Preferred embodiments can be found below and in the claims.

A manipulator arm for a robot according to the disclosure comprises a printed circuit board motor and a transmission, the printed circuit board motor comprising a multi-layer board having at least one first solenoid coil, which comprises flat coils lying vertically on top of each other, the flat coils being connected electrically in series or in parallel, two vertically adjacent coils being orthogonally offset to each other in each case such that, in a cross-section perpendicular to the surface of the multi-layer board, conducting track portions of the one flat coil are arranged in partial overlap vertically with two conducting track portions of the other flat coil. The printed circuit board motor and the transmission can be arranged, for example, in a manipulator arm joint or robot arm joint, wherein two manipulator arm segments are connected to one another in an articulated manner. The printed circuit board motor is a so-called brushless PCB motor, which comprises a stator and a rotor, wherein, for example, a plurality of permanent magnets, which alternate in their orientation of the north and south poles, are arranged on the rotor and the multi-layer board with the respective solenoid coil, comprising the flat coils stacked on top of each other, is arranged on the stator.

A multi-layer board is to be understood to mean a multi-layer board designed as a printed circuit board, which has a plurality of levels lying vertically on top of each other, each of which is equipped with conducting tracks designed as flat coils. The respective solenoid coil can be supplied with electric power, so that the rotor can be set in motion, in particular in rotational motion, as a result of the current flow within the conducting tracks.

Alternatively, the respective solenoid coil of the multi-layer board is arranged on the rotor, which is at least indirectly connected to a first manipulator arm segment of the manipulator arm via the transmission. The respective solenoid coil interacts with at least one permanent magnet, which is at least indirectly arranged on a stator, which is at least indirectly connected to a second manipulator arm connected to a joint with the first manipulator arm.

The printed circuit board motor can be designed as an axial flux motor or as a radial flux motor. In a radial flux motor, the rotor can be arranged at least in sections radially inside the stator, with the magnetic field being aligned radially with respect to the axis of rotation of the rotor. In contrast, the magnetic field of an axial flux motor is aligned axially to the axis of rotation of the rotor. Axial flux motors feature high torque density, which improves the load capacity of the manipulator arm.

The various layers of the multi-layer board that encompass the respective flat coil are essentially filled with windings that can be energized. Windings lying on top of each other each form a coil of one phase of the motor. The flat coils can first be applied to individual circuit boards or individual layers consisting of a PCB substrate, the individual circuit boards being stacked on top of one another to form the multi-layer board. In particular, a flat coil can be arranged on each individual circuit board both on the upper side and on the underside in order to reduce the number of individual circuit boards and to stack the flat coils with a smaller vertical spacing from one another. In other words, the flat coils are arranged at a distance from one another in the vertical direction.

If the flat coils lying vertically on top of each other are electrically connected in series, electrical pressure contacts are provided, with each individual flat coil being wound, for example, spirally in its respective plane. It is advantageous to wind a first flat coil, which is located in the top or bottom level of the circuit board, in a spiral from the inside to the outside. In contrast, the second flat coil, which is vertically adjacent to the first, is wound spirally from the outside to the inside. The third flat coil is again wound inside out, and so on.

In this context, a spiral course of the winding is to be understood to mean any type of winding in which the individual windings of the flat coil are formed by a single planar conducting track and enclose one another in one plane. In this case, the conducting track routing can, for example, have curves or be angular.

The orthogonal or laterally offset arrangement of the flat coils that are respectively adjacent in the vertical direction improves the thermal conductivity of the multi-layer board. Thus, heat generated by energizing the solenoid coil is dissipated to the outside faster. For this purpose, conducting track portions of the vertically adjacent flat coils are arranged partially covering or overlapping one another, so that the heat generated in an inner turn of a flat coil is transferred comparatively easily to a turn of a vertically and orthogonally adjacent flat coil, which is closer to the edge of the multi-layer board in the lateral direction. Preferably, the distance between the printed conductor portions of flat coils, which are partially overlapping vertically, is smaller than the distance between two turns that are arranged in the same plane of the printed circuit board or the multi-layer board. The orthogonal offset of the superimposed flat coils means that the cross section of the multi-layer board is interspersed with conducting track portions over its entire transverse extent. The heat transfer between two conducting track portions takes place mainly in the vertical direction, where there is relatively low thermal resistance due to the small distance between the flat coils.

The multi-layer board preferably has a plurality of solenoid coils, all of the solenoid coils being designed in accordance with the solenoid coil described above. The solenoid coils are arranged side by side or adjacent, with the outer conducting track portions of the adjacent flat coils of the two adjacent solenoid coils being able to be arranged partially overlapping in order to further improve the heat transport to the surface of the circuit board. Such a multi-layer board with a plurality of solenoid coils comprises a primary part as a circuit board, with the solenoid coils being operatively connected to a secondary part on which the permanent magnets are arranged. An air gap is formed between the multi-layer board with the solenoid coils and the permanent magnets.

The respective multi-layer board is preferably interspersed with at least one coil core orthogonally to the surface of the multi-layer board. The coil core can be made of a ferromagnetic or ferrimagnetic material and preferably extends perpendicularly to the plane of the respective multi-layer board or the flat coils. The magnetic flux generated by the respective solenoid coil can be bundled by the coil core, thereby increasing the magnetic flux density. When using the printed circuit board in an electric motor, the increase in the magnetic flux density means that the effect of the magnetic force increases. As a result, the printed circuit board motor can provide greater force or torque. The coil core is preferably made of iron.

Furthermore, the transmission is preferably designed as a strain wave transmission, as a cycloidal transmission or as a planetary transmission with at least one planetary gear stage.

The disclosure includes the technical teaching that a controller is provided for controlling and regulating the printed circuit board motor. In other words, the flat coils of the respective solenoid coil are supplied with electrical energy and thereby cause the permanently connected permanent magnets to move relative to the coil, whereby, as previously described, the manipulator arm segments can be positioned relative to one another around the manipulator arm joint.

The manipulator arm preferably has at least one angle encoder for detecting an angular position of the manipulator arm. The manipulator arm can have a number of manipulator arm segments which are connected to one another via respective joints. The printed circuit board motor can be arranged together with the transmission in such a joint, with the manipulator arm of the robot being movable by means of the printed circuit board motor and the gear, which are controlled and regulated by the controller, and the relative angular position of two manipulator arm segments connected to one another via the respective joint being adjustable with respect to each other. The movement of the manipulator arm is monitored by means of the respective angle encoder, which can detect the precise angular position of one manipulator arm segment relative to the other manipulator arm segment. For this purpose, the respective angle encoder is connected to the controller.

The disclosure also relates to a robot comprising at least one manipulator arm of the type described above. The manipulator arm preferably has one or more manipulator arm segments which are connected to one another in an articulated manner via a respective robot joint. A respective drive, at least consisting of the printed circuit board motor and the transmission, is integrated in the joint. Furthermore, an angle encoder is preferably integrated in the joint. The robot arm segments connected to one another via the joint can be adjusted relative to one another about an axis of rotation. Several manipulator arm segments thus form a manipulator arm of the robot. In this sense, the disclosure proposes to use a printed circuit board motor in a manipulator arm of the type previously described. As a result, the manipulator arm can be produced in a cost-effective manner, with the external dimensions, the weight and the inertia of the manipulator arm in particular being reduced. This in turn has a positive effect on the safety of the robot, whose respective manipulator arm increases in terms of speed of movement and load capacity due to the improved properties.

### BRIEF DESCRIPTION OF THE DRAWINGS

Further measures are described below together with two preferred exemplary embodiments according to the disclosure using the figures. In the figures,

FIG. 1 shows a highly schematic view of a manipulator arm according to the disclosure of a robot according to the disclosure according to a first embodiment,

FIG. 2 shows a cross section through a multi-layer board of a circuit board motor of the manipulator arm according to FIG. 1, and

FIG. 3 shows a cross section of a multi-layer board of the printed circuit board motor according to a second embodiment.

### DETAILED DESCRIPTION

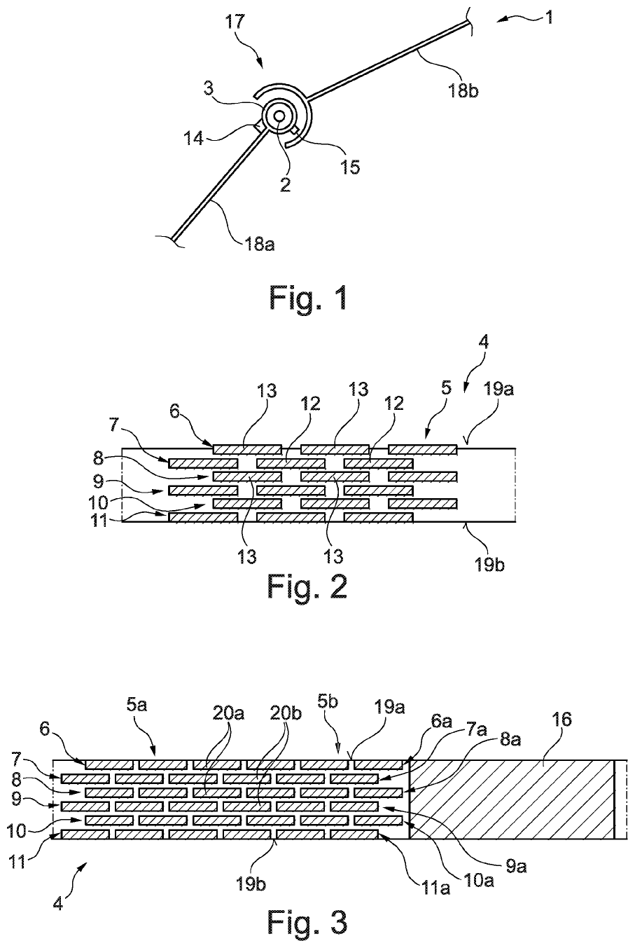

According to FIG. 1, a manipulator arm 1 of a robot—only partially shown here—is shown in a highly schematic and simplified manner. In the present case, the manipulator arm 1 has a horizontally arranged robot joint 17 with two manipulator arm segments 18a, 18b articulated above it. To position the first manipulator arm segment 18a relative to the second manipulator arm segment 18b, a printed circuit board motor 2 and a transmission 3 are arranged on the robot joint 17 of the manipulator arm 1, wherein the printed circuit board motor 2 is set up to set an angular position of the first manipulator arm segment 18a relative to the second manipulator arm segment 18b by energization.

The printed circuit board motor 2 is a so-called PCB motor, which, according to FIGS. 2 and 3, has a multi-layer board 4 with at least one solenoid coil 5, which comprises multiple vertical flat coils 6, 7, 8, 9, 10, 11 lying on top of each other. The multi-layer board 4 is arranged on a stator—not shown—or rotor—also not shown—which is at least indirectly non-rotatably connected to one of the manipulator arm segments 18a, 18b. On the other hand, a plurality of permanent magnets—not shown here—are arranged at least indirectly on the respective other manipulator arm segment 18a, 18b, which permanent magnets are arranged at a distance from the respective solenoid coil 5 of the multi-layer board 4 due to an air gap, and as a result of an energization of the printed circuit board motor 2 or the respective solenoid coil 5 and a magnetic field generated thereby, the rotor is made to rotate with respect to the stator, so that the first manipulator arm 18a is displaced with respect to the second manipulator arm 18b, or vice versa. The control and regulation of the actuating movement of the respective manipulator arm segment 18a, 18b is carried out by a controller 14 arranged on the manipulator arm 1.

The transmission 3 acts as a step-down transmission or as a speed reducer and in the present case is designed as a strain wave transmission. Alternatively, the transmission 3 can also be designed as a cycloidal transmission or as a planetary transmission with at least one planetary gear stage. Furthermore, an angle encoder 15 for detecting an angular position of the first manipulator arm 18a relative to the second manipulator arm 18b, or vice versa, is arranged on the manipulator arm 1 in the area of the robot joint 17. The angle encoder 15 is also connected to the controller 14, which processes the measured variables detected and uses them to control or regulate the actuating movement of the manipulator arm 1.

According to FIG. 2, the printed circuit board motor 2 has a multi-layer board 4 with a solenoid coil 5, which comprises six flat coils 6, 7, 8, 9, 10, 11 lying vertically on top of each other. The first and second flat coils 6, 7, the third and fourth flat coils 8, 9 and the fifth and sixth flat coils 10, 11 are each printed on a single layer—not shown here—with the single layers being stacked to form the multi-layer board 4. The individual layers are individual circuit boards, each consisting of a PCB substrate (“Printed Circuit Board” substrate). In other words, the first, the third or the fifth flat coil 6, 8, 10 is arranged on the upper side of the respective individual layer while the second, the fourth or the sixth flat coil 7, 9, 11 is arranged on the respective underside of the respective individual layer. The flat coils 6, 7, 8, 9, 10, 11 are electrically connected to one another, and depending on the requirements of the printed circuit board motor 2, individual or multiple flat coils 6, 7, 8, 9, 10, 11 can be electrically connected in series or in parallel.

Vertically directly adjacent flat coils 6, 7, 8, 9, 10, 11 are offset to each other in the orthogonal or transverse direction, whereby as a result, a first conducting track portion 12 of the second flat coil 7 partially overlaps vertically on the one hand with two conducting track portions 13 of the first flat coil 6, and on the other hand is arranged with two conducting track portions 13 of the third flat coil 8. In other words, two vertically adjacent flat coils 6, 7, 8, 9, 10, 11 are arranged orthogonally or laterally offset to each other in such a way that, in a cross section perpendicular to the surface 19a, 19b of the multi-layer board 4, conducting track portions 12 of one flat coil 6, 7, 8, 9, 10, 11 are arranged vertically in partial overlap with two conducting track portions 13 of the respective other flat coil 6, 7, 8, 9, 10, 11. Since this results in a smaller distance between the turns of the adjacent flat coils 6, 7, 8, 9, 10, 11 in the vertical direction, heat transport to the surfaces 19a, 19b of the circuit board 4 is improved. The distances between the flat coils 6, 7, 8, 9, 10, 11 in the vertical direction depends on the thickness of the PCB substrate of the individual layers.

According to an alternative embodiment according to FIG. 3, the multi-layer board 4 has two solenoid coils 5a, 5b, which are arranged next to one another. The first solenoid coil 5a, which is arranged on the left in the present figure, comprises six flat coils 6, 7, 8, 9, 10, 11, which are arranged vertically on top of each other and are arranged according to FIG. 2. These flat coils 6, 7, 8, 9, 10, 11 are comb-like in the immediately laterally adjacent second solenoid coil 5b, which is arranged on the right in the present figure, also with six flat coils 6a, 7a, 8a, 9a, 10a, 11a. The engagement is in the area of the respective outer conducting track portions 20a, 20b. In other words, an outer conducting track portion 20a of the first solenoid coil 5a is vertically arranged in partial overlap with at least one outer conducting track portion 20b of the second solenoid coil 5b. As a result, heat is transported particularly effectively between the two solenoid coils 5a, 5b and to the surface 19a, 19b. For the rest, the heat transfer takes place analogously to the solenoid coil 5 according to FIG. 2. A large number of solenoid coils 5 can thus be arranged next to one another in a simple manner, with sufficient overlapping of the conducting track portions always being ensured between the adjacent solenoid coils 5 in order to improve the thermal behavior.

The multi-layer board 4 has a coil core 16 passing through it orthogonally to the surface 19a, 19b of the multi-layer board 4. In the present case, the coil core 16 is made of iron and extends through the multi-layer board 4 perpendicularly to the surfaces 19a, 19b. The magnetic flux generated by the solenoid coils 5a, 5b can be bundled by the coil core 16, thereby increasing the magnetic flux density.

### LIST OF REFERENCE NUMERALS

1 manipulator arm
2 circuit board motor
3 transmission
4 multi-layer board
5 solenoid coil
5a first solenoid coil
5b second solenoid coil
6 first flat coil of the first solenoid coil
6a first flat coil of the second solenoid coil
7 second flat coil of the first solenoid coil
7a second flat coil of the second solenoid coil
8 third flat coil of the first solenoid coil
8a third flat coil of the second solenoid coil
9 fourth flat coil of the first solenoid coil
9a fourth flat coil of the second solenoid coil
10 fifth flat coil of the first solenoid coil
10a fifth flat coil of the second solenoid coil
11 sixth flat coil of the first solenoid coil
11a sixth flat coil of the second solenoid coil
12 first conducting track portion
13 second conducting track portion
14 controller
15 angle encoder
16 coil core
17 robot joint
18a, 18b manipulator arm segment
19a, 19b surface of the multi-layer board
20a, 20b outer track portion

1. A manipulator arm for a robot, comprising:
a printed circuit board motor and a transmission;
the printed circuit board motor comprises a multi-layer board having at least one first solenoid coil, which comprises flat coils lying vertically on top of each other, and the flat coils are connected electrically in series or in parallel;
two vertically adjacent ones of the flat coils are arranged orthogonally offset with respect to each other such that, in a cross-section perpendicular to a surface of the multi-layer board, conducting track portions of one of the two vertically adjacent flat coils are arranged vertically in partial overlap with two conducting track portions of an other of the two vertically adjacent flat coils.

2. The manipulator arm according to claim 1, further comprising at least one coil core that passes through the multi-layer board orthogonally to the surface of the multi-layer board.

3. The manipulator arm according to claim 1, wherein the transmission comprises a strain wave transmission.

4. The manipulator arm according to claim 1, wherein the transmission comprises a cycloidal transmission.

5. The manipulator arm according to claim 1, wherein the transmission comprises a planetary transmission with at least one planetary gear stage.

6. The manipulator arm according to claim 1, further comprising a controller configured to control and regulate the printed circuit board motor.

7. The manipulator arm according to claim 6, further comprising at least one angle encoder configured to detect an angular position of the manipulator arm.

8. (canceled)

9. A robot, comprising at least one manipulator arm according to claim 1.

10. A manipulator arm for a robot, comprising:
a printed circuit board motor including a multi-layer board having at least one first solenoid coil, which comprises flat coils lying vertically on top of each other, and the flat coils are connected electrically in series or in parallel; and
two vertically adjacent ones of the flat coils are arranged orthogonally offset with respect to each other such that, in a cross-section perpendicular to a surface of the multi-layer board, conducting track portions of one of the two vertically adjacent flat coils are arranged vertically in partial overlap with two conducting track portions of an other of the two vertically adjacent flat coils.

11. The manipulator arm according to claim 10, further comprising at least one coil core that passes through the multi-layer board orthogonally to the surface of the multi-layer board.

12. The manipulator arm according to claim 10, further comprising a strain wave transmission connected to the printed circuit board motor.

13. The manipulator arm according to claim 10, further comprising a cycloidal transmission connected to the printed circuit board motor.

14. The manipulator arm according to claim 10, further comprising a planetary transmission with at least one planetary gear stage connected to the printed circuit board motor.

15. The manipulator arm according to claim 10, further comprising a controller configured to control and regulate the printed circuit board motor.

16. The manipulator arm according to claim 15, further comprising at least one angle encoder configured to detect an angular position of the manipulator arm.
